(19) United States
(12) Patent Application Publication
(10) Pub. No.: US 2024/0250064 A1
(43) Pub. Date: Jul. 25, 2024

(54) SUBSTRATE PROCESSING METHOD

(71) Applicant: Tokyo Electron Limited, Tokyo (JP)

(72) Inventors: Yoshihisa MATSUBARA, Tokyo (JP); Yoshihiro TSUTSUMI, Tokyo (JP); Yohei YAMASHITA, Kumamoto (JP)

(21) Appl. No.: 18/562,502

(22) PCT Filed: May 25, 2022
(86) PCT No.: PCT/JP2022/021409

§ 371 Date: Nov. 20, 2023

(30) Foreign Application Priority Data
Jun. 3, 2021 (JP) 2021-093400

(51) Int. Cl. H01L 23/00; B32B 43/00; H01L 23/544

(52) U.S. Cl. CPC H01L 24/96; B32B 43/006; H01L 23/544; H01L 2223/54426; H01L 2224/96

(57) ABSTRACT

The substrate processing method includes processes (A) to (D). The process (A) prepares a laminated substrate including a first substrate, a first absorption layer that absorbs laser light, a second absorption layer having an absorption coefficient with respect to the laser light higher than that of the first absorption layer, a device layer, and a second substrate in this order. The process (B) irradiates the laser light with respect to the first substrate from a side opposite to the second substrate. The process (C) irradiates the laser light transmitted through the first substrate on the first absorption layer, to form a modified layer in the first absorption layer. The process (D) separates the first substrate and the second substrate from each other using the modified layer as a starting point.

### TECHNICAL FIELD

The present disclosure relates to substrate processing methods.

### BACKGROUND ART

A stripping method described in Patent Document 1 includes the steps of forming a separation layer, which is a laminate of a light absorption layer made of amorphous silicon and a reflection layer made of a metal thin film, for example, on a transparent substrate, forming a transferred layer directly on the separation layer or via a predetermined intermediate layer, and bonding a transfer body to a side of the transferred layer opposite to the substrate via a bonding layer. In addition, the stripping method includes the step of irradiating the separation layer with irradiation light, such as laser light, from a back surface side of the substrate to generate ablation in the light absorption layer, thereby causing stripping of the separation layer in and/or at an interface of the separation layer, and separating the transferred layer from the substrate so as to transfer the transferred layer to the transfer body.

A stripping method described in Patent Document 2 is a stripping method for stripping a support body, adhered to a wafer via an adhesive layer, from the wafer, and including the steps of supplying a solvent, which causes swelling of the adhesive layer and reduces adhesion at a surface of the adhesive layer, to the adhesive layer, and stripping the swollen adhesive layer from the wafer. A separation layer, which is modified by absorbing light irradiated via the support body, is further provided between the support body and the adhesive layer. The separation layer includes a light absorber which is decomposed by light or the like. Graphite powder, black titanium oxide powder, or the like is used as the light absorber.

A composite laminate described in Patent Document 3 includes a light transmitting support body, a latent release layer disposed on the light transmitting support body, a bonding layer disposed on the latent release layer, and a thermoplastic undercoat layer disposed on the bonding layer. The latent release layer includes a photothermal conversion layer. The photothermal conversion layer includes an absorber, and a heat decomposable resin disposed adjacent to the bonding layer. The absorber includes carbon black.

### PRIOR ART DOCUMENTS

### Patent Documents

Patent Document 1: Japanese Laid-Open Patent Publication No. H10-125929
Patent Document 2: Japanese Laid-Open Patent Publication No. 2014-049698
Patent Document 3: Japanese Laid-Open Patent Publication No. 2015-513211

### DISCLOSURE OF THE INVENTION

### Problems to be Solved by the Invention

One aspect of the present disclosure provides a technique for reducing damage to a device layer caused by laser light.

### Means of Solving the Problem

A substrate processing method according to one aspect of the present disclosure includes the following (A) to (D). (A) prepares a laminated substrate including a first substrate, a first absorption layer that absorbs laser light, a second absorption layer having an absorption coefficient with respect to the laser light higher than that of the first absorption layer, a device layer, and a second substrate in this order. (B) irradiates the laser light with respect to the first substrate from a side opposite to the second substrate. (C) irradiates the laser light transmitted through the first substrate on the first absorption layer, to form a modified layer in the first absorption layer. (D) separates the first substrate and the second substrate from each other using the modified layer as a starting point.

### Effects of the Invention

According to one aspect of the present disclosure, it is possible to reduce damage to a device layer caused by laser light.

### BRIEF DESCRIPTION OF THE DRAWINGS

FIG. 1 is a flow chart illustrating a substrate processing method according to one embodiment.

FIG. 2 is a cross sectional view of step S1 according to a first exemplary implementation.

FIG. 3 is a cross sectional view of step S4 according to the first exemplary implementation.

FIG. 4 is a cross sectional view of step S5 according to the first exemplary implementation.

FIG. 5 is a cross sectional view of step S6 according to the first exemplary implementation.

FIG. 6 is a cross sectional view of step S7 according to the first exemplary implementation.

FIG. 7 is a cross sectional view of step S8 according to the first exemplary implementation.

FIG. 8 is a cross sectional view of step S1 according to a second exemplary implementation.

FIG. 9 is a cross sectional view of step S4 according to the second exemplary implementation.

FIG. 10 is a cross sectional view of step S5 according to the second exemplary implementation.

FIG. 11 is a cross sectional view of step S6 according to the second exemplary implementation.

FIG. 12 is a cross sectional view of step S7 according to the second exemplary implementation.

FIG. 13 is a cross sectional view illustrating a second substrate after a first substrate and the second substrate are separated according to a third exemplary implementation.

FIG. 14 is a cross sectional view illustrating the second substrate after removing a second absorption layer according to the third exemplary implementation.

FIG. 15 is a cross sectional view illustrating a detection of an alignment mark according to the third exemplary implementation.

FIG. 16 is a cross sectional view illustrating the detection of the alignment mark according to a fourth exemplary implementation.

FIG. 17A is a diagram illustrating an example of a transmittance of a cold filter including 40 layers.

FIG. 17B is a diagram illustrating an example of the transmittance of the cold filter including 20 layers.

FIG. 17C is a diagram illustrating an example of the transmittance of the cold filter including 10 layers.

FIG. 18A is a diagram illustrating an example of a total transmittance of a silicon substrate and the cold filter.

FIG. 18B is an enlarged view of a part of FIG. 18A.

FIG. 19 is a TEM image of the silicon substrate and the cold filter used for a measurement of the transmittance of FIG. 18A and FIG. 18B.

### MODE OF CARRYING OUT THE INVENTION

Hereinafter, embodiments of the present disclosure will be described with reference to the drawings. In the drawings, the same or corresponding constituent elements are designated by the same reference numerals, and a description thereof may be omitted.

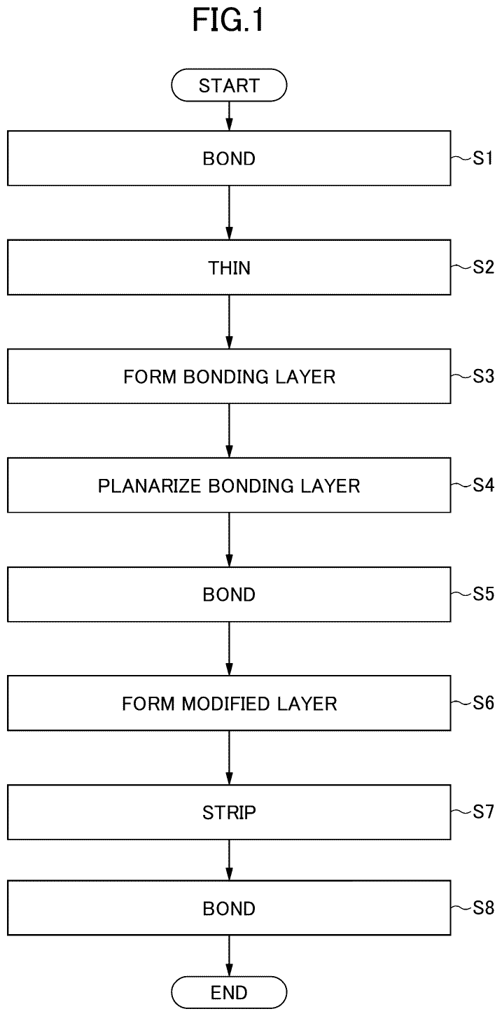

A substrate processing method according to one embodiment will be described with reference to FIG. 1. The substrate processing method includes steps S1 through S8, for example. The substrate processing method may include steps other than steps S1 through S8. Further, the substrate processing method may not include all of steps S1 through S8.

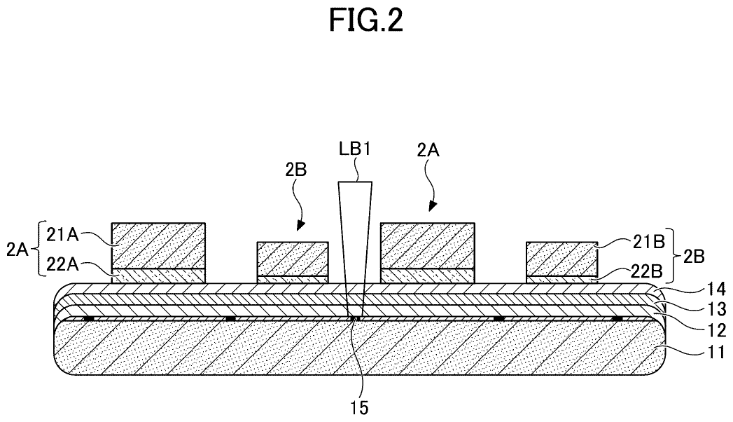

In step S1, a first substrate 11 and chips 2A and 2B are bonded to obtain a laminated substrate, as illustrated in FIG. 2. Before the bonding, a first absorption layer 12 that absorbs laser light LB2 which will be described later, a second absorption layer 13 having an absorption coefficient with respect to the laser light LB2 higher than that of the first absorption layer 12, and a bonding layer 14 are formed in this order on the first substrate 11, for example.

The first substrate 11 is a silicon wafer. The first substrate 11 may be a compound semiconductor wafer. The compound semiconductor wafer is not particularly limited, and is a GaAs wafer, a SiC wafer, a GaN wafer, an InP wafer, or an AlN wafer, for example.

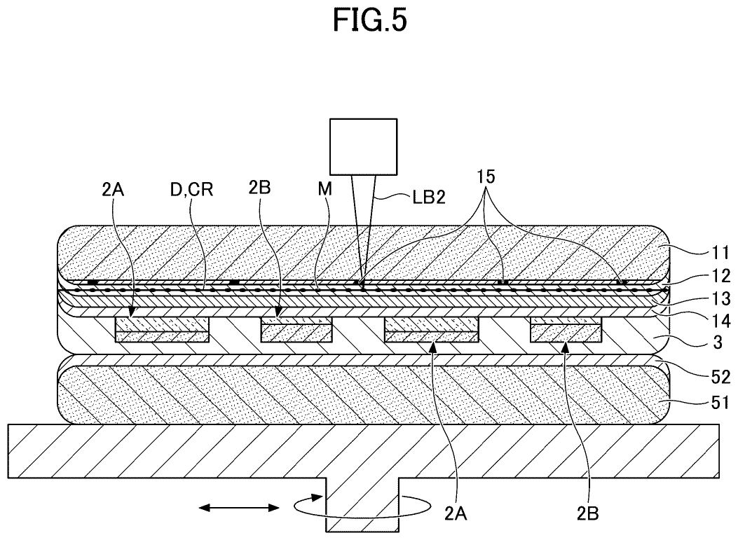

The first absorption layer 12 is disposed between the first substrate 11 and the chips 2A and 2B. Although details will be described later, the laser light LB2 is transmitted through the first substrate 11, and is irradiated on the first absorption layer 12, as illustrated in FIG. 5. The laser light LB2 is absorbed by the first absorption layer 12, to form a modified layer M in the first absorption layer 12. The first absorption layer 12 is a silicon oxide layer, for example, and is formed by thermal oxidation, chemical vapor deposition (CVD), or the like.

The first absorption layer 12 need only absorb the laser light LB2 to such an extent that the modified layer M can be formed, and may be a silicon nitride layer, a silicon carbonitride layer, or the like. The silicon nitride layer is formed by thermal nitriding, CVD, or the like. The silicon carbonitride layer is formed by CVD or the like.

The second absorption layer 13 absorbs the laser light LB2 that cannot be sufficiently absorbed by the first absorption layer 12. Because the chips 2A and 2B are hardly irradiated with the laser light LB2, damage to the chips 2A and 2B, particularly device layers 22A and 22B, can be reduced. The absorption coefficient of the second absorption layer 13 with respect to the laser light LB2 is higher than that of the first absorption layer 12. Hence, compared to a case where the laser light LB2 is absorbed to the same extent solely by the first absorption layer 12, the entire thickness can be reduced.

The second absorption layer 13 transmits detection light LB1. The detection light LB1 is used to detect an alignment mark 15. The alignment mark 15 is used for alignment when bonding the first substrate 11 and the chips 2A and 2B, or used for measurement of a positional error after the bonding. The alignment mark 15 may be used for both the alignment and the measurement of the positional error. A measurement result of the positional error after the bonding is used for alignment when bonding the first substrate 11 and the chip at a next or subsequent occasions, for example. In addition, the measurement result of the positional error after the bonding may be used for quality control, such as determining defective products or the like.

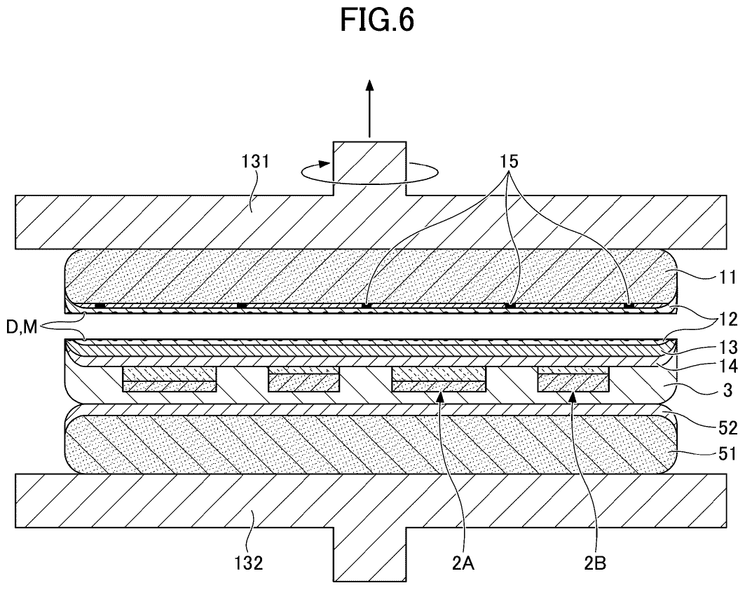

The alignment mark 15 is formed between the first substrate 11 and the first absorption layer 12, for example. As will be described later, the alignment mark 15 remains attached to the first substrate 11 after the first substrate 11 and the chips 2A and 2B are separated from one another, with the modified layer M formed in the first absorption layer 12 as a starting point (refer to FIG. 6). Accordingly, when reusing the first substrate 11, it is unnecessary to form the alignment mark 15 again, and the alignment mark 15 can be reused.

The alignment mark 15 is detected using the detection light LB1. For example, the alignment mark 15 is irradiated with the detection light LB1 in a direction opposite to the direction of the laser light LB2, and the detection light LB1 is irradiated on the alignment mark 15 from a side opposite to the first substrate 11. The detection light LB1 is transmitted through the bonding layer 14, the second absorption layer 13, and the first absorption layer 12, and is irradiated on the alignment mark 15.

The detection light LB1 is infrared light, for example. The alignment mark 15 is imaged by an infrared camera, for example. A wavelength of the detection light LB1 is different from a wavelength of the laser light LB2, and is 1000 nm to 2000 nm, and preferably 1000 nm to 1200 nm, for example.

The alignment mark 15 absorbs the detection light LB1, for example. In this case, a light source of the detection light LB1 and the infrared camera are arranged so that the alignment mark 15 is interposed therebetween. The alignment mark 15 may reflect the detection light LB1. In this case, the light source of the detection light LB1 and the infrared camera are arranged on one side (the same side) of the alignment mark 15.

As illustrated in FIG. 5, the alignment mark 15 transmits the laser light LB2. The laser light LB2 is transmitted through the first substrate 11 and the alignment mark 15, to form the modified layer M in the first absorption layer 12. A plurality of modified layers M are formed on a dividing surface D. The dividing surface D may be set inside the first absorption layer 12, or may be set at an interface between the first absorption layer 12 and the first substrate 11.

A wavelength of the laser light LB2 is 8800 nm to 11000 nm, for example. The alignment mark 15 has a transmittance greater than or equal to 45% and less than or equal to 100%, preferably greater than or equal to 50% and less than or equal to 100%, and more preferably greater than or equal to 60% and less than or equal to 100% with respect to the laser light LB2, for example.

The alignment mark 15 may absorb the detection light LB1 and also transmit the laser light LB2. In this case, the alignment mark 15 is formed of a Ge film, a SiGe film, a metal silicide film, an AlN film, or the like, for example. The alignment mark 15 may reflect the detection light LB1 and also transmit the laser light LB2.

As described above, the second absorption layer 13 transmits the detection light LB1 and also absorbs the laser light LB2. The second absorption layer 13 is a so-called cold filter or the like. The second absorption layer 13 has a high refractive index layer, and a low refractive index layer having a refractive index lower than that of the high refractive index layer, that are arranged alternately and repeatedly, for example. A material used for the high refractive index layer is titanium oxide or ruthenium oxide, for example. On the other hand, a material used for the low refractive index layer is silicon oxide, for example.

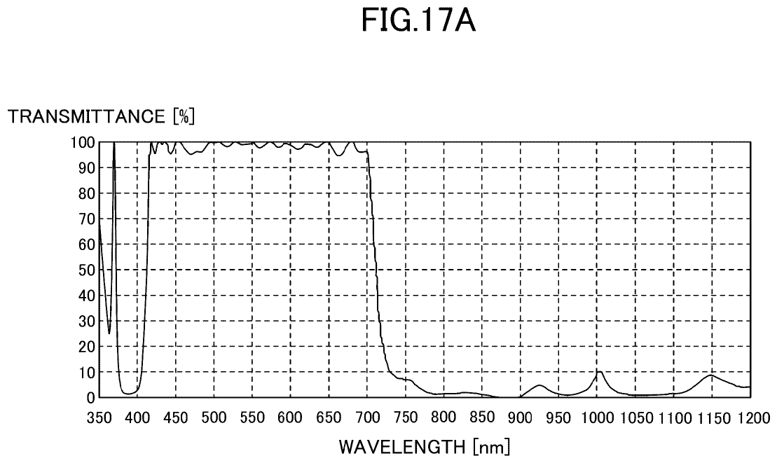

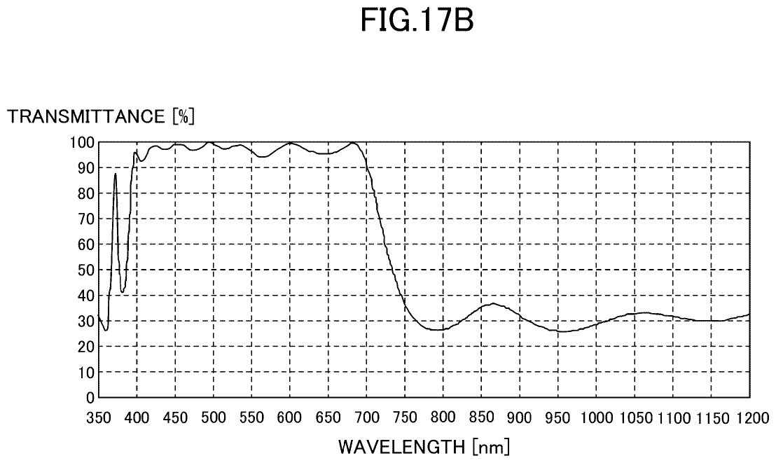

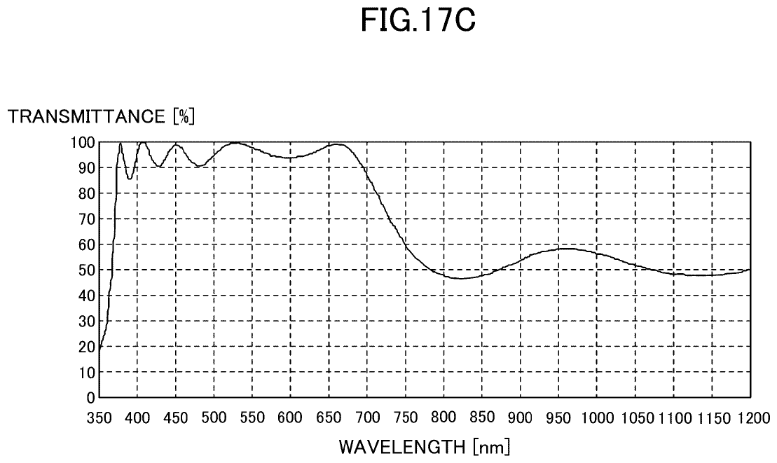

An example of a transmittance of a cold filter having titanium dioxide layers and silicon oxide layers amounting to a total of 40 layers, and a total thickness of 3.5 μm, is illustrated in FIG. 17A. In addition, an example of a transmittance of a cold filter having titanium dioxide layers and silicon oxide layers amounting to a total of 20 layers, and a total thickness of 1.56 μm, is illustrated in FIG. 17B. Further, an example of a transmittance of a cold filter having titanium dioxide layers and silicon oxide layers amounting to a total of 10 layers, and a total thickness of 0.82 μm, is illustrated in FIG. 17C. As is evident from FIG. 17A through FIG. 17C, in a case where the wavelength of the detection light LB1 is 1000 nm to 1200 nm, the total number of titanium dioxide layers and silicon oxide layers is preferably set in a range of 10 to 20. FIG. 17A through FIG. 17C illustrate simulation results of the transmittance obtained solely for the cold filter (without the silicon substrate).

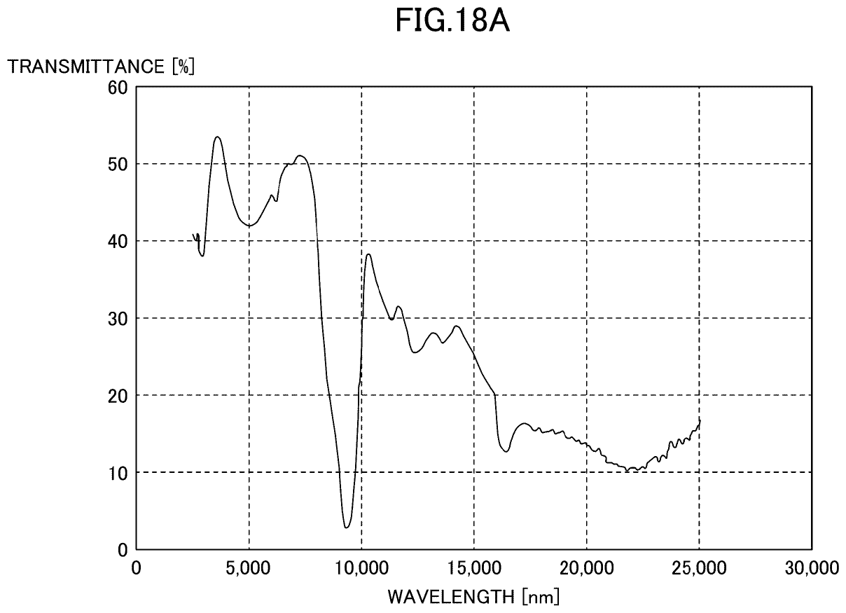

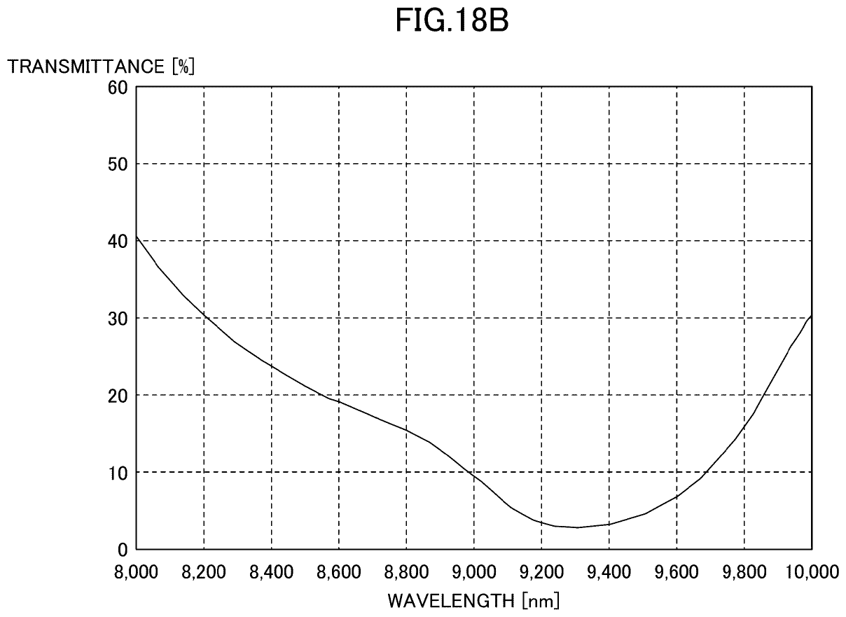

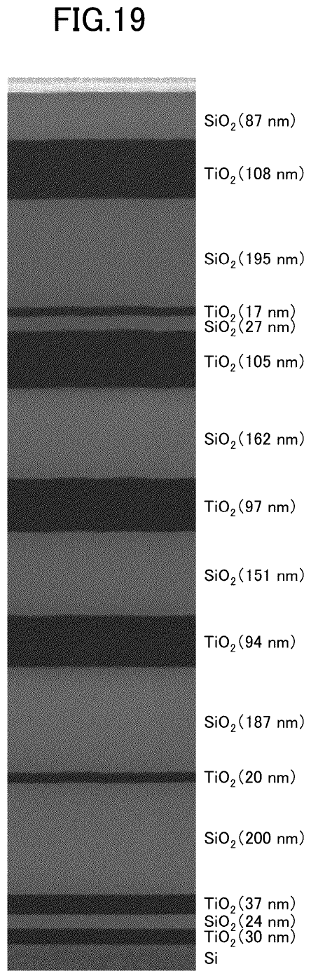

A cold filter having titanium dioxide layers and silicon oxide layers amounting to a total of 16 layers is formed on a silicon substrate, and measurement results of a total transmittance of the silicon substrate and the cold filter are illustrated in FIG. 18A and FIG. 18B. FIG. 18B is an enlarged view of a part of FIG. 18A. As is evident from FIG. 18A and FIG. 18B, in a case where the wavelength is 8800 nm to 11000 nm, the transmittance was less than or equal to 40%. In a case where the wavelength is 9300 nm, the transmittance was less than or equal to 5%. A TEM image of the silicon substrate and the cold filter used for the measurement of the transmittance of FIG. 18A and FIG. 18B is illustrated in FIG. 19. In FIG. 19, “Si”, “SiO₂”, and “TiO₂” indicate materials of the respective layers, and numerical values in brackets indicate thicknesses of the respective layers.

As illustrated in FIG. 2, the bonding layer 14 is disposed between the second absorption layer 13 and the chips 2A and 2B, and makes contact with the chips 2A and 2B. The bonding layer 14 is an insulating layer, such as a silicon oxide layer or the like, for example. A material used for the bonding layer 14 may be different from or the same as a material used for the first absorption layer 12. A bonding surface of the bonding layer 14 opposing the chips 2A and 2B may be surface-modified by plasma or the like before bonding, or may be hydrophilized using pure water or the like.

The surface modification cuts the bond of SiO₂ at the bonding surface, forms a dangling bond of Si, and enables hydrophilization of the bonding surface, for example. Under a reduced pressure atmosphere, an oxygen gas, which is used as a processing gas, for example, is excited to be plasmatized, and ionized. Oxygen ions are irradiated on the bonding surface, and the bonding surface is modified. The processing gas is not limited to the oxygen gas, and may be a nitrogen gas or the like, for example.

The hydrophilization supplies pure water, such as deionized water (DIW) or the like, to the bonding surface rotated by a spin chuck. An OH group attaches to the dangling bond of Si at the bonding surface, and the bonding surface is hydrophilized.

The chip 2A has a second substrate 21A, and a device layer 22A. The device layer 22A is formed on an upper surface of the second substrate 21A. The second substrate 21A is a silicon wafer, for example, but may be a compound semiconductor wafer. The device layer 22A includes a semiconductor element, a circuit, a terminal, or the like. The device layer 22A may include at least one of a transistor, a device isolation, and an interconnect. After forming the device layer 22A, the second substrate 21A is singulated into a plurality of chips 2A.

Similar to the chip 2B, the chip 2A has a second substrate 21B and a device layer 22B. The second substrate 21B is a silicon wafer, for example, but may be a compound semiconductor wafer. The device layer 22B has functions different from those of the device layer 22A, and the chip 2A has a thickness different from that of the chip 2B. The device layer 22B may include at least one of a transistor, a device isolation, and an interconnect. After forming the device layer 22B, the second substrate 21B is singulated into a plurality of chips 2B.

Bonding surfaces of the chips 2A and 2B opposing the bonding layer 14 may be surface-modified by plasma or the like before bonding, or may be hydrophilized using pure water or the like.

In step S1, the chips 2A and 2B are temporarily bonded, one by one, to the first substrate 11. The chips 2A and 2B are bonded to the first substrate 11 with the device layers 22A and 22B facing the first substrate 11. The chips 2A and 2B and the first substrate 11 are bonded to one another by Van der Waals force (intermolecular force), hydrogen bonding of OH groups, or the like, without using a liquid adhesive. Thereafter, a heat treatment may be performed to increase a bonding strength.

According to the present embodiment, the chips 2A and 2B are temporarily bonded to the first substrate 11, and thereafter separated from the first substrate 11. For this reason, no problem occurs even if air bubbles are caught between the first substrate 11 and the chips 2A and 2B when the chips 2A and 2B and the first substrate 11 are bonded to one another. Accordingly, in step S1, the chips 2A and 2B can be bonded to the first substrate 11 in a state where the chips 2A and 2B are held in a flat state. Because the chips 2A and 2B are not deformed, it is possible to improve an accuracy of position control of the chips 2A and 2B, and accurately place the chips 2A and 2B to target positions.

In addition, according to the present embodiment, the chips 2A and 2B are temporarily bonded to the first substrate 11 and then separated from the first substrate 11. For this reason, no problem occurs even if particles are caught between the first substrate 11 and the chips 2A and 2B when the chips 2A and 2B and the first substrate 11 are bonded to one another. Accordingly, the bonding surface of the bonding layer 14 and the bonding surfaces of the chips 2A and 2B may be contaminated to such an extent that does not affect the bonding, and the required cleanliness can be reduced.

Next, in step S2, although not illustrated, the chips 2A and 2B are thinned to make the thicknesses of the chips 2A and 2B uniform. In the chips 2A and 2B, the second substrates 21A and 21B are thinned, but the device layers 22A and 22B are not thinned. The thinning includes grinding or laser beam machining.

Next, in step S3, although not illustrated, the bonding layer 3 is formed on the surfaces of the chips 2A and 2B. Similar to the bonding layer 14, the bonding layer 3 is an insulating layer, such as a silicon oxide layer or the like, and is formed by CVD or the like. The chips 2A and 2B are spaced apart from one another and arranged to form an uneven surface. Because the bonding layer 3 is formed on the uneven surface, the surface of the bonding layer 3 also includes an unevenness.

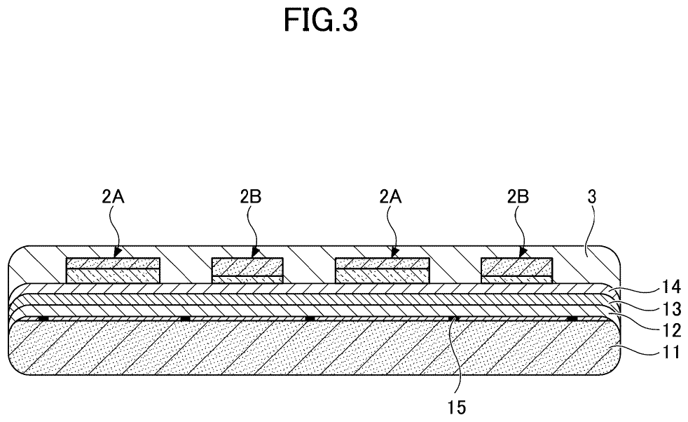

Next, in step S4, the surface of the bonding layer 3 is planarized, as illustrated in FIG. 3. The planarization of the surface of the bonding layer 3 includes laser beam machining and chemical mechanical polishing (CMP) in this order, for example. When convex portions are removed by the laser beam machining, a time required to perform the CMP can be shortened. Step S4 may include only one of the laser beam machining and the CMP.

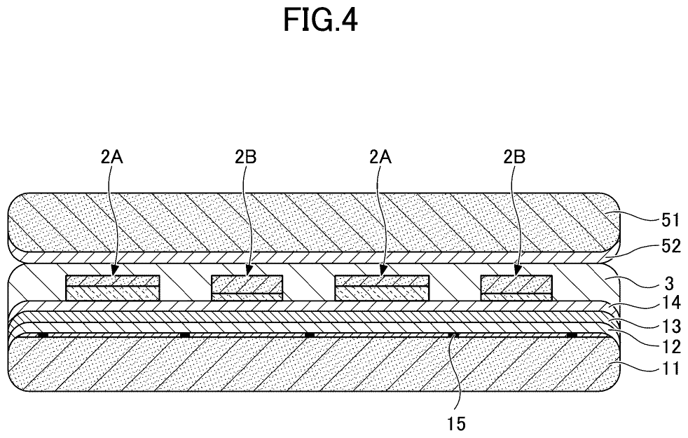

Next, in step S5, the chips 2A and 2B are bonded to a third substrate 51, as illustrated in FIG. 4. Before the bonding, a bonding layer 52 is formed on a bonding surface of the third substrate 51 opposing the chips 2A and 2B. The third substrate 51 is a silicon wafer, for example, but may be a compound semiconductor wafer. The bonding layer 52 is an insulating layer, such as a silicon oxide layer or the like, and is formed by CVD or the like. The chips 2A and 2B and the third substrate 51 are bonded to one another by Van der Waals force (intermolecular force), hydrogen bonding of OH groups, or the like, without using a liquid adhesive.

The third substrate 51 is deformed into a downwardly convex curved surface in order to prevent catching air bubbles, is gradually bonded from a center toward a periphery thereof, and finally returns to a flat surface. The third substrate 51 can be deformed by fixing a peripheral edge of the third substrate 51, and pressing the center of the third substrate 51 downward. In a case where the third substrate 51 is deformed, the deformation can be made with ease compared to the case where the chips 2A and 2B are deformed one by one, because an interval between the fixing position and the pressing position of the third substrate 51 is wide. The deformation is easy because the substrates are bonded together.

The arrangement of the third substrate 51 and the first substrate 11 may be reversed, and the third substrate 51 may be arranged below the first substrate 11. In this case, the third substrate 51 is deformed into an upwardly convex curved surface in order to prevent catching air bubbles. In addition, although the third substrate 51 is first subjected to the bending deformation so that the bonding between the chips 2A and 2B and the third substrate 51 gradually progresses from the center toward the peripheral edge, the first substrate 11 may be first subjected to the bending deformation. However, from a viewpoint of protecting the chips 2A and 2B, it is preferable to hold the first substrate 11 in the flat state and to hold the chips 2A and 2B in the flat state.

Next, in step S6, the laser light LB2 is irradiated with respect to the first substrate 11 from the side opposite to the second substrates 21A and 21B, as illustrated in FIG. 5, and the laser light LB2 transmitted through the first substrate 11 is irradiated on the first absorption layer 12, to form the modified layer M in the first absorption layer 12. The plurality of modified layers M are formed on the dividing surface D. The modified layers M are formed in a dot pattern, at a light condensing point or above the light condensing point, for example.

The laser light LB2 is transmitted through the first substrate 11, and is irradiated on the first absorption layer 12, to form the modified layer M in the first absorption layer 12. The first absorption layer 12 is disposed between the first substrate 11 and the chips 2A and 2B, and absorbs the laser light LB2. In addition, the second absorption layer 13 is disposed between the first absorption layer 12 and the chips 2A and 2B, and absorbs the laser light LB2 that cannot be sufficiently absorbed by the first absorption layer 12. Because the chips 2A and 2B are hardly irradiated with the laser light LB2, damage to the chips 2A and 2B, particularly device layers 22A and 22B, can be reduced.

The laser light LB2 has a wavelength of 8800 nm to 11000 nm, for example, so that the laser light LB2 is transmitted through the first substrate 11 and the alignment mark 15 and is absorbed by the first absorption layer 12. A source of the laser light LB2 is a CO₂ laser, for example. A wavelength of CO₂ laser is approximately 9300 nm. The laser light LB2 is pulse-oscillated.

A forming position of the modified layer M is moved by a galvano scanner or an XYθ stage. The galvano scanner moves the laser light LB2. The XYθ stage moves the first substrate 11 in a horizontal direction (the X-axis direction and the Y-axis direction), and rotates the first substrate 11 around a vertical axis. An XYZθ stage may be used in place of the XYθ stage.

The plurality of modified layers M are formed at intervals in a circumferential direction and a radial direction of the first substrate 11. A crack CR connecting the modified layers M is also formed when forming the modified layers M.

Next, in step S7, the first substrate 11 and the second substrates 21A and 21B are separated from one another using the modified layer M as the starting point, as illustrated in FIG. 6, and the chips 2A and 2B and the first substrate 11 are separated from one another. First, an upper chuck 131 holds the first substrate 11, and a lower chuck 132 holds the third substrate 51. However, the arrangement of the first substrate 11 and the third substrate 51 may be reversed, and the upper chuck 131 may hold the third substrate 51 and the lower chuck 132 may hold the first substrate 11. Next, when the upper chuck 131 is raised with respect to the lower chuck 132, the crack CR spreads in a plane using the modified layer M as the starting point, and the chips 2A, 2B and the first substrate 11 are separated from one another at the dividing surface D.

In step S7, the upper chuck 131 may be rotated around the vertical axis as the upper chuck 131 is raised. The first substrate 11 and the second substrates 21A and 21B can be cut at the dividing surface D. The lower chuck 132 may be lowered in place of raising the upper chuck 131, or in addition to raising the upper chuck 131. Further, the lower chuck 132 may be rotated around the vertical axis.

After step S7 and before step S8 that follows, a portion of the first absorption layer 12, the second absorption layer 13, and the bonding layer 14 remaining on the chips 2A and 2B may be removed by CMP or the like. As a result, the device layers 22A and 22B of the chips 2A and 2B are exposed again. The device layers 22A and 22B are semiconductor memories, for example.

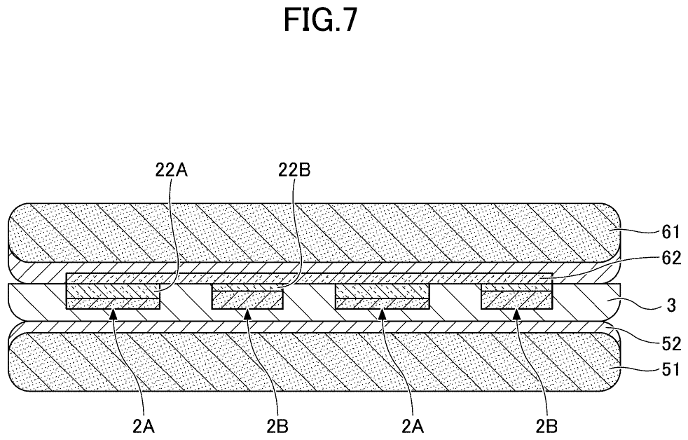

Next, in step S8, the chips 2A and 2B are bonded to a device layer 62 that is formed on a fourth substrate 61, in a state where the chips 2A and 2B are bonded to the third substrate 51, as illustrated in FIG. 7. The fourth substrate 61 is a silicon wafer, for example, but may be a compound semiconductor wafer. The device layer 62 includes a semiconductor element, a circuit, a terminal, or the like, and is electrically connected to the device layers 22A and 22B of the chips 2A and 2B. The device layer 62 includes a peripheral circuit (also referred to as a “peripheral”) of a semiconductor memory, an input-output circuit (also referred to as an “IO”) of the semiconductor memory, or the like.

The chips 2A and 2B and the fourth substrate 61 are bonded to one another by Van der Waals force (intermolecular force), hydrogen bonding of OH groups, or the like, without using a liquid adhesive. The fourth substrate 61 is deformed into a downwardly convex curved surface in order to prevent catching air bubbles, is gradually bonded from a center toward a periphery thereof, and finally returns to a flat surface.

The fourth substrate 61 can be deformed by fixing a peripheral edge of the fourth substrate 61, and pressing the center of the fourth substrate 61 downward. In a case where the fourth substrate 61 is deformed, the deformation can be made with ease compared to the case where the chips 2A and 2B are deformed one by one, because an interval between the fixing position and the pressing position of the fourth substrate 61 is wide. The deformation is easy because the substrates are bonded together.

The arrangement of the fourth substrate 61 and the third substrate 51 may be reversed, and the fourth substrate 61 may be arranged below the third substrate 51. In this case, the fourth substrate 61 is deformed into an upwardly convex curved surface in order to prevent catching air bubbles. In addition, although the fourth substrate 61 is first subjected to the bending deformation so that the bonding between the chips 2A and 2B and the fourth substrate 61 gradually progresses from the center toward the peripheral edge, the third substrate 51 may be first subjected to the bending deformation.

A substrate with attached chips is obtained by step S8. The substrate with the attached chips includes the fourth substrate 61, and the plurality of chips 2A and 2B. The substrate with the attached chips further includes the third substrate 51. The third substrate 51 may be separated from the chips 2A and 2B, and the substrate with the attached chips need only include the fourth substrate 61 and the chips 2A and 2B.

As described above, according to the present embodiment, in order to obtain the substrate with the attached chips, the plurality of chips 2A and 2B are not bonded one by one to one surface of the fourth substrate 61, but are first temporarily bonded to one surface of the first substrate 11. Because catching the air bubbles at this stage does not cause a problem, the chips 2A and 2B can be bonded to the first substrate 11 in a state where the chips 2A and 2B are held in the flat state. Because it is unnecessary to forcibly deform the chips 2A and 2B, it is possible to improve the accuracy of the position control of the chips 2A and 2B, and accurately the chips 2A and 2B to the target positions.

Thereafter, the plurality of chips 2A and 2B bonded to the first substrate 11 are bonded to the third substrate 51. Next, the plurality of chips 2A and 2B and the first substrate 11 are separated from one another. Next, the plurality of chips 2A and 2B are bonded with respect to the device layer 62 formed on the fourth substrate 61, in a state where the chips 2A and 2B are bonded to the third substrate 51.

In this state, the fourth substrate 61 is deformed into a curved surface in order to prevent catching air bubbles, is gradually bonded from the center toward the peripheral edge, and finally returns to the flat surface. In a case where the fourth substrate 61 is deformed, the deformation can be made with ease compared to the case where the chips 2A and 2B are deformed one by one. The deformation is easy because the substrates are bonded together. For this reason, compared to a case where the chips 2A and 2B are permanently bonded to the fourth substrate 61 without performing the step of temporarily bonding the chips 2A and 2B to the first substrate 11, it is possible to obtain the substrate with the attached chips, including no air bubbles that are caught and excellent positional accuracy.

In addition, according to the present embodiment, after the chips 2A and 2B and the first substrate 11 are separated from one another, the first substrate 11 is provided with the alignment marks 15. Accordingly, when reusing the first substrate 11, it is unnecessary to form the alignment marks 15 again, and the alignment marks 15 can be reused.

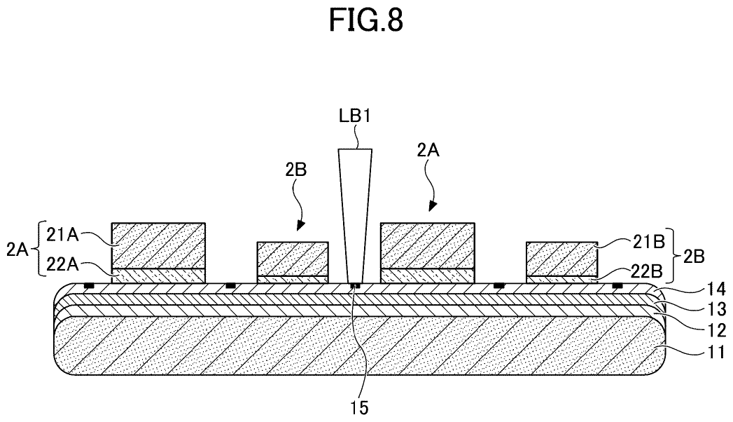

Next, a second embodiment of the substrate processing method illustrated in FIG. 1 will be described, with reference to FIG. 8 through FIG. 12. In the second embodiment, the alignment mark 15 is arranged between the second absorption layer 13 and the chips 2A and 2B, as illustrated in FIG. 8. Hereinafter, differences of the second embodiment from the first embodiment will mainly be described.

In step S1, the first substrate 11 and the chips 2A and 2B are bonded to one another to obtain a laminated substrate, as illustrated in FIG. 8. Before the bonding, the first absorption layer 12 that absorbs laser light LB2, the second absorption layer 13 having the absorption coefficient with respect to the laser light LB2 higher than that of the first absorption layer 12, and the bonding layer 14 may be formed in this order on the first substrate 11, similar to the first embodiment.

The alignment mark 15 is detected using the detection light LB1, similar to the first embodiment. For example, the alignment mark 15 is irradiated with the detection light LB1 in the direction opposite to the direction of the laser light LB2, and the detection light LB1 is irradiated on the alignment mark 15 from the side opposite to the first substrate 11. The detection light LB1 is irradiated on the alignment mark 15 by being transmitted between the chips 2A and 2B that are adjacent to each other, for example.

The alignment mark 15 reflects the detection light LB1, for example. A reflectivity can be adjusted by a refractive index difference. In a case where the alignment mark 15 reflects the detection light LB1, the light source of the detection light LB1 and the infrared camera are arranged on one side (the same side) of the alignment mark 15. When the second absorption layer 13 absorbs the detection light LB1 as will be described later, a luminance difference between the alignment mark 15 and a periphery thereof is large in the image captured by the infrared camera, and the detection accuracy of the alignment mark 15 is high. The second absorption layer 13 of the second embodiment may absorb the detection light LB1, in contrast to the second absorption layer 13 of the first embodiment that transmits the detection light LB1 as described above. This is because the detection light LB1 of the first embodiment is irradiated on the alignment mark 15 via the second absorption layer 13, as illustrated in FIG. 2.

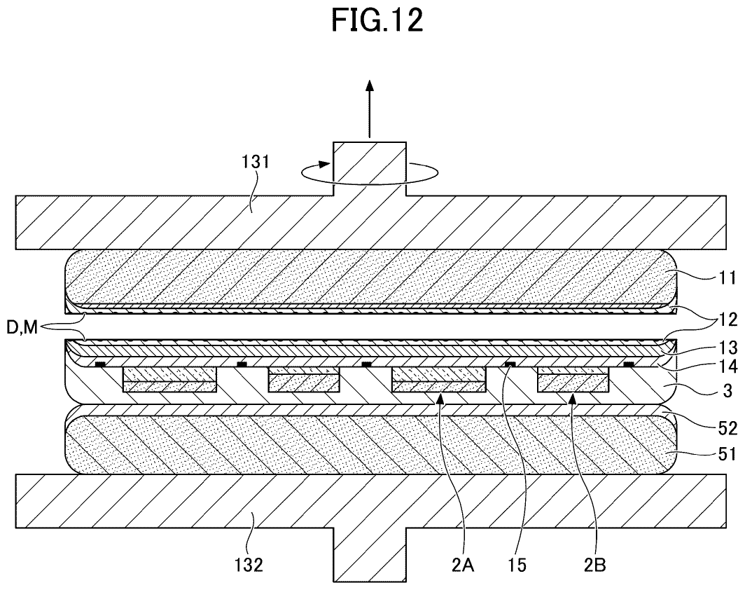

Unlike the first embodiment, the alignment marks 15 are disposed between the second absorption layer 13 and the chips 2A and 2B, and are formed on the bonding surface of the bonding layer 14 facing the chips 2A and 2B, for example. As will be described later, after the first substrate 11 and the chips 2A and 2B are separated from one another using the modified layer M formed in the first absorption layer 12 as the starting point, the alignment marks 15 remain attached to the chips 2A and 2B (refer to FIG. 12). Accordingly, the alignment mark 15 can be utilized in a post-processing performed with respect to the chips 2A and 2B.

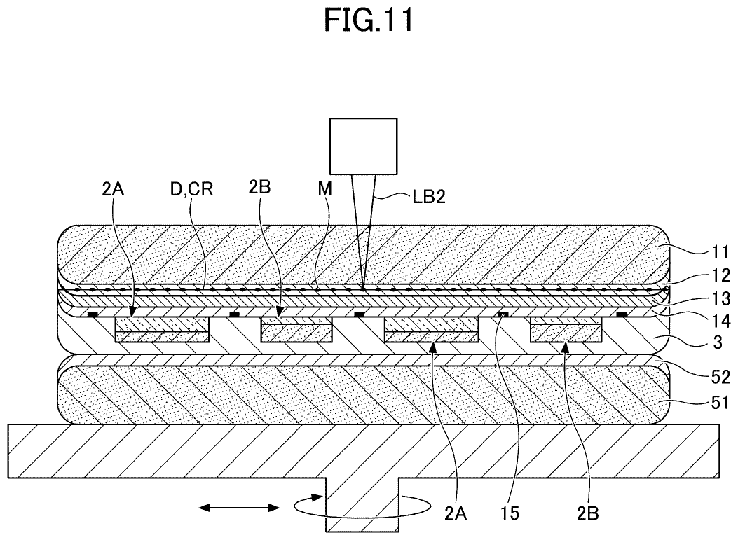

Unlike the first embodiment, because the alignment mark 15 is not formed between the first substrate 11 and the first absorption layer 12, the alignment mark 15 is not required to transmit the laser light LB2 and may absorb the laser light LB2. As illustrated in FIG. 11, the laser light LB2 is transmitted through the first substrate 11, and is irradiated on the first absorption layer 12, to form the modified layer M in the first absorption layer 12.

The second absorption layer 13 absorbs the laser light LB2 that cannot be sufficiently absorbed by the first absorption layer 12, similar to the first embodiment. Because the chips 2A and 2B are hardly irradiated with the laser light LB2, damage to the chips 2A and 2B, particularly the device layers 22A and 22B, can be reduced. The absorption coefficient of the second absorption layer 13 with respect to the laser light LB2 is higher than that of the first absorption layer 12. Hence, compared to the case where the laser light LB2 is absorbed to the same extent solely by the first absorption layer 12, the entire thickness can be reduced.

Unlike the first embodiment, the second absorption layer 13 absorbs the detection light LB1. In the image captured by the infrared camera, the luminance difference between the alignment mark 15 and the periphery thereof is large, and the detection accuracy of the alignment mark 15 is high. The second absorption layer 13 includes a black absorber, for example. The black absorber includes black titanium or black carbon, for example.

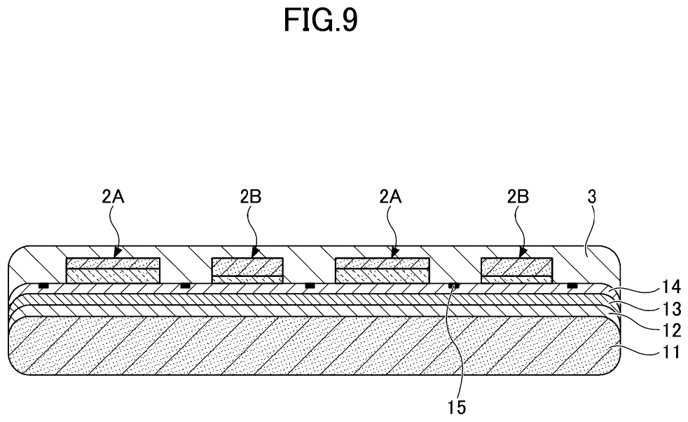

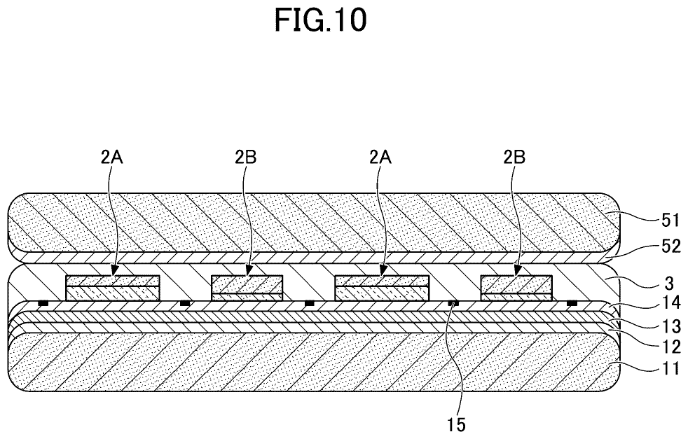

Next, in step S2, although not illustrated, the chips 2A and 2B are thinned to make the thicknesses of the chips 2A and 2B uniform. Next, in step S3, although not illustrated, the bonding layer 3 is formed on the surfaces of the chips 2A and 2B. Next, in step S4, the surface of the bonding layer 3 is planarized, as illustrated in FIG. 9. Next, in step S5, the chips 2A and 2B are bonded to the third substrate 51, as illustrated in FIG. 10.

Next, in step S6, the laser light LB2 is irradiated with respect to the first substrate 11 from the side opposite to the second substrates 21A and 21B, and the laser light LB2 transmitted through the first substrate 11 is irradiated on the first absorption layer 12, to form the modified layer M in the first absorption layer 12, as illustrated in FIG. 11. A plurality of modified layers are formed on the dividing surface D. The first absorption layer 12 is disposed between the first substrate 11 and the chips 2A and 2B, and absorbs the laser light LB2. The second absorption layer 13 is disposed between the first absorption layer 12 and the chips 2A and 2B, and absorbs the laser light LB2 that cannot be sufficiently absorbed by the first absorption layer 12. Because the chips 2A and 2B are hardly irradiated with the laser light LB2, damage to the chips 2A and 2B, particularly the device layers 22A and 22B, can be reduced.

Next, in step S7, the first substrate 11 and the second substrates 21A and 21B are separated from one another, using the modified layer M as the starting point, and the chips 2A and 2B and the first substrate 11 are separated from one another, as illustrated in FIG. 12. The crack CR spreads in a plane using the modified layer M as the starting point, and the chips 2A and 2B and the first substrate 11 are separated from one another at the dividing surface D.

After step S7 described above and before step S8 described below, a portion of the first absorption layer 12, the second absorption layer 13, and the bonding layer 14 remaining on the chips 2A and 2B may be removed by CMP or the like. As a result, the device layers 22A and 22B of the chips 2A and 2B become exposed again. The device layers 22A and 22B are semiconductor memories, for example.

Next, in step S8, as illustrated in FIG. 7, the chips 2A and 2B are bonded to the device layer 62 that is formed on the fourth substrate 61, in a state where the chips 2A and 2B are bonded to the third substrate 51, similar to the first embodiment. The device layer 62 is electrically connected to the device layers 22A and 22B of the chips 2A and 2B. The device layer 62 is a peripheral circuit or an input-output circuit of a semiconductor memory, for example. In step S8 described above, the substrate with the attached chips is obtained.

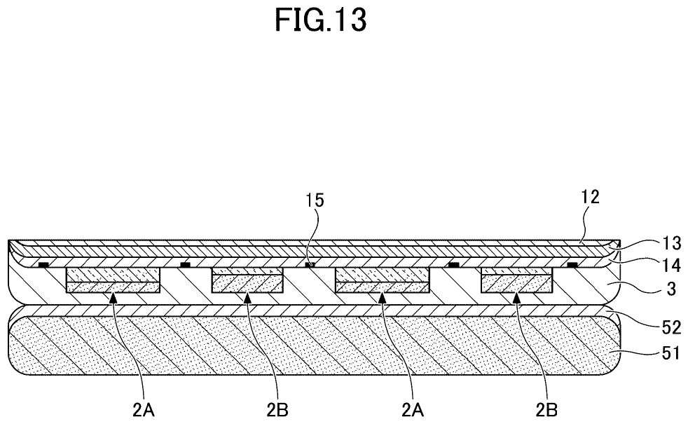

Next, a substrate processing method according to a third embodiment will be described, with reference to FIG. 13 through FIG. 15. In the third embodiment, after the first absorption layer 12 is irradiated with the laser light LB2, the alignment mark 15 is irradiated with the detection light LB1. In the third embodiment, the alignment mark 15 is irradiated with the detection light LB1 in the same direction as the direction of the laser light LB2. Hereinafter, differences of the third embodiment from the second embodiment will mainly be described.

In the third embodiment, similar to step S6 of the second embodiment, the laser light LB2 is irradiated with respect to the first substrate 11 from the side opposite to the second substrates 21A and 21B, and the laser light LB2 transmitted through the first substrate 11 is irradiated on the first absorption layer 12, to form the modified layer M in the first absorption layer 12, as illustrated in FIG. 11. A plurality of modified layers are formed on the dividing surface D.

Next, in the third embodiment, similar to step S7 of the second embodiment, the first substrate 11 and the second substrates 21A and 21B are separated from one another using the modified layer M as the starting point, and the chips 2A and 2B and the first substrate 11 are separated from one another, as illustrated in FIG. 12. As a result, the alignment marks 15 remain on the chips 2A and 2B, as illustrated in FIG. 13. A portion of the first absorption layer 12 and the second absorption layer 13 remain on the chips 2A and 2B, in addition to the alignment marks 15.

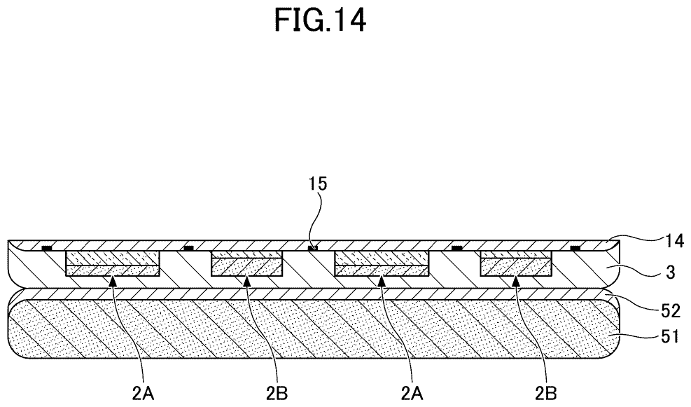

Next, in the third embodiment, a portion of the first absorption layer 12 and the second absorption layer 13 are removed by CMP or the like, as illustrated in FIG. 14. The bonding layer 14 may be removed, or may not be removed as illustrated in FIG. 14. The alignment marks 15 are not removed and remain on the chips 2A and 2B. Accordingly, as will be described later, the alignment marks 15 can be utilized in the post-processing performed with respect to the chips 2A and 2B.

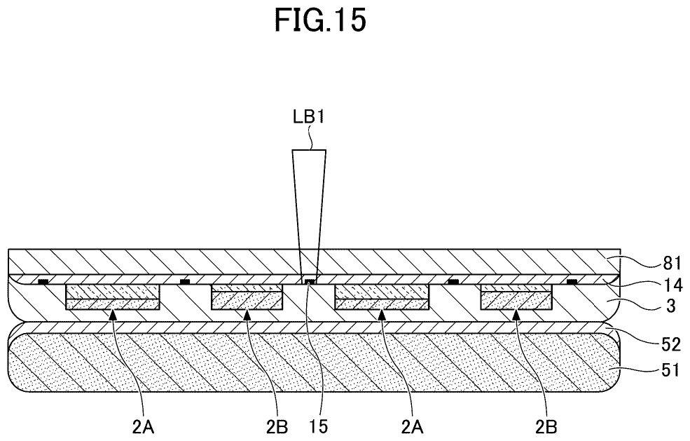

Next, in the third embodiment, an insulating layer 81 is formed on the chips 2A and 2B, as illustrated in FIG. 15. The insulating layer 81 is a silicon oxide layer or the like, for example. The alignment mark 15 is used to adjust the position of a via formed in the insulating layer 81, or the like. The alignment mark 15 is detected using the detection light LB1.

For example, the detection light LB1 is irradiated with respect to the alignment mark 15 in the same direction as the direction of the laser light LB2. The detection light LB1 is transmitted through the insulating layer 81 and the bonding layer 14, and is irradiated with respect to the alignment mark 15. The alignment mark 15 may absorb or reflect the detection light LB1. The detection light LB1 is infrared ray, for example, and the alignment mark 15 is imaged by an infrared camera, for example.

As described above, the detection light LB1 is irradiated with respect to the alignment mark 15 in the same direction as the direction of the laser light LB2. It is unnecessary to vertically turn the chips 2A and 2B upside down between the case where the laser light LB2 is irradiated and the case where the detection light LB1 is irradiated. Accordingly, a mechanism for vertically turning the chips 2A and 2B upside down is not required, and a configuration of a substrate processing apparatus can be simplified.

In the present embodiment, because the second absorption layer 13 is removed before irradiating the detection light LB1, the second absorption layer 13 does not need to transmit the detection light LB1. Hence, the second absorption layer 13 may be formed of a material that absorbs the laser light LB2 and also absorbs the detection light LB1. A structure of the second absorption layer 13 can be simplified. The second absorption layer 13 includes a black absorber or the like, for example.

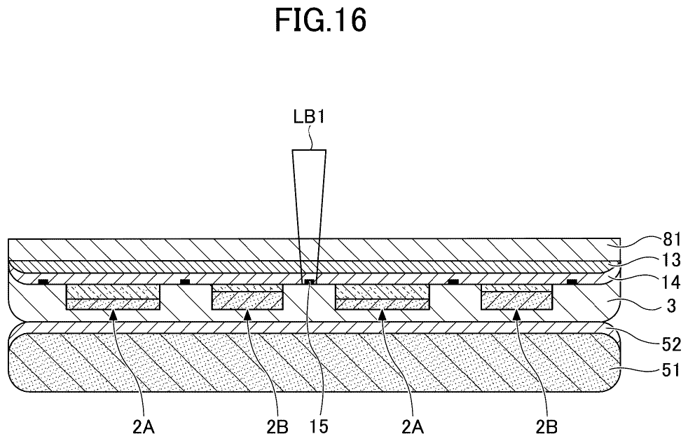

Next, a substrate processing method according to a fourth embodiment will be described, with reference to FIG. 16. In the fourth embodiment, unlike the third embodiment, the second absorption layer 13 is not removed by CMP or the like after the chips 2A and 2B and the first substrate 11 are separated from one another, and the second absorption layer 13 remains. Hereinafter, differences of the fourth embodiment from the third embodiment will mainly be described.

In the fourth embodiment, when forming the insulating layer 81 on the chips 2A and 2B, the insulating layer 81 is formed on the second absorption layer 13, as illustrated in FIG. 16. The insulating layer 81 is a silicon oxide layer or the like, for example. The alignment mark 15 is used to adjust the position of the via formed in the insulating layer 81, or the like. The alignment mark 15 is detected using the detection light LB1.

For example, the detection light LB1 is irradiated with respect to the alignment mark 15 in the same direction as the direction of the laser light LB2. The detection light LB1 is transmitted through the insulating layer 81, the second absorption layer 13, and the bonding layer 14, and is irradiated with respect to the alignment mark 15. The alignment mark 15 may absorb or reflect the detection light LB1. The detection light LB1 is infrared ray, for example, and the alignment mark 15 is imaged by an infrared camera, for example.

As described above, the detection light LB1 is irradiated with respect to the alignment mark 15 in the same direction as the direction of the laser light LB2. It is unnecessary to vertically turn the chips 2A and 2B upside down between the case where the laser light LB2 is irradiated and the case where the detection light LB1 is irradiated. Accordingly, the mechanism for vertically turning the chips 2A and 2B upside down is not required, and the configuration of the substrate processing apparatus can be simplified.

In the present embodiment, the detection light LB1 is transmitted through the second absorption layer 13. The second absorption layer 13 absorbs the laser light LB2, and transmits the detection light LB1. The second absorption layer 13 is a so-called cold filter or the like. The second absorption layer 13 has a high refractive index layer, and a low refractive index layer having a refractive index lower than that of the high refractive index layer, that are arranged alternately and repeatedly, for example.

In the first embodiment, the second embodiment, the third embodiment, and the fourth embodiment described above, the chips 2A and 2B including the device layers 22A and 22B and the second substrates 21A and 21B are bonded to the first substrate 11 at intervals, but the technique of the present disclosure is not limited to Chip to Wafer (C2W), and may be applied to Wafer to Wafer (W2W).

In other words, although not illustrated, the second substrate having the device layer formed thereon may be bonded to the first substrate having the same size as the second substrate. The first substrate and the second substrate need only have the bonding surfaces having the same size. In this case, the device layer formed on the second substrate and the first substrate are separated from each other by separating the first substrate and the second substrate from each other using the modified layer M as the starting point.

Although the embodiments of the substrate processing method according to the present disclosure is described above, the present disclosure is not limited to the embodiments described above or the like. Various variations, modifications, substitutions, additions, deletions, and combinations are possible within the scope defined in the claims. These also fall within the technical scope of the present disclosure.

This application is based upon and claims priority to Japanese Patent Application No. 2021-093400 filed before the Japan Patent Office on Jun. 3, 2021, and the entire contents of which are incorporated herein by reference.

### DESCRIPTION OF REFERENCE NUMERALS

11: First substrate
12: First absorption layer
13: Second absorption layer
21A, 21B: Second substrate
22A, 22B: Device layer
M: Modified layer
LB2: Laser light

1. A substrate processing method comprising:
preparing a laminated substrate including a first substrate, a first absorption layer configured to absorb laser light, a second absorption layer having an absorption coefficient with respect to the laser light higher than an absorption coefficient of the first absorption layer, a device layer, and a second substrate in this order;
irradiating the laser light with respect to the first substrate from a side opposite to the second substrate;
irradiating the laser light transmitted through the first substrate on the first absorption layer, to form a modified layer in the first absorption layer; and
separating the first substrate and the second substrate using the modified layer as a starting point.

2. The substrate processing method as claimed in claim 1, wherein the laminated substrate includes an alignment mark, and further comprising:
irradiating detection light that is used to detect the alignment mark in a direction identical to a direction of the laser light with respect to the alignment mark.

3. The substrate processing method as claimed in claim 1, wherein the laminated substrate includes an alignment mark, and further comprising:
irradiating detection light that is used to detect the alignment mark in a direction opposite to a direction of the laser light with respect to the alignment mark.

4. The substrate processing method as claimed in claim 1, wherein
the laminated substrate includes an alignment mark, and
the alignment mark is disposed between the first substrate and the first absorption layer.

5. The substrate processing method as claimed in claim 1, wherein
the laminated substrate includes an alignment mark, and
the alignment mark is disposed between the second absorption layer and the device layer.

6. The substrate processing method as claimed in claim 1, wherein
the laminated substrate includes an alignment mark, and
the second absorption layer absorbs the laser light, and transmits detection light that is used to detect the alignment mark.

7. The substrate processing method as claimed in claim 6, wherein the second absorption layer includes a high refractive index layer and a low refractive index layer that are arranged alternately and repeatedly.

8. The substrate processing method as claimed in claim 1, wherein
the laminated substrate includes an alignment mark, and
the second absorption layer absorbs the laser light, and absorbs detection light that is used to detect the alignment mark.

9. The substrate processing method as claimed in claim 8, wherein the second absorption layer includes a black absorber.

10. The substrate processing method as claimed in claim 1, further comprising:
bonding a plurality of chips including the device layer and the second substrate to the first substrate at intervals,
wherein the plurality of chips and the first substrate are separated from one another by separating the first substrate and the second substrate from each other using the modified layer as a starting point.

11. The substrate processing method as claimed in claim 1, further comprising:
bonding the second substrate having the device layer formed thereon to the first substrate having a size identical to a size of the second substrate,
wherein the device layer formed on the second substrate and the first substrate are separated from each other by separating the first substrate and the second substrate from each other using the modified layer as a starting point.

12. The substrate processing method as claimed in claim 1, wherein the laser light has a wavelength of 8800 nm to 11000 nm.
